(19) United States
(12) Patent Application Publication
(10) Pub. No.: US 2026/0009841 A1
(43) Pub. Date: Jan. 8, 2026

(54) TESTING APPARATUS AND BURN-IN DEVICE

(71) Applicant: Materials Analysis Technology Inc., Zhubei City (TW)

(72) Inventors: TSUNG-KUI CHOU, Zhubei City (TW); HUNG-JEN CHEN, Hsinchu City (TW)

(21) Appl. No.: 18/926,764

(22) Filed: Oct. 25, 2024

(30) Foreign Application Priority Data
Jul. 3, 2024 (TW) 113124809

(51) Int. Cl. G01R 31/28

(52) U.S. Cl. CPC G01R 31/2874; G01R 31/2862; G01R 31/2863

(57) ABSTRACT

A testing apparatus includes an apparatus body, a processing device, a temperature adjustment device, an N number of DC power supply modules, and a burn-in device. The apparatus body includes a chamber, the processing device controls the temperature adjustment device so that a temperature of the chamber reaches a predetermined temperature. The burn-in device includes a circuit board and an M number of chip carriers. When a side of the circuit board is plugged into a mating connector of the chamber, a power supply pin of a chip under test disposed on the chip carrier is electrically connected to one of the DC power supply modules. The processing device performs a test process to the chip under test through a testing circuit. The testing circuit is not disposed on the circuit board and is disposed in the processing device or the DC power supply module.

### CROSS-REFERENCE TO RELATED PATENT APPLICATION

This application claims the benefit of priority to Taiwan Patent Application No. 113124809, filed on Jul. 3, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a testing apparatus and burn-in device, and more particularly to a testing apparatus configured to enable a plurality of chips under test in a test process at a predetermined temperature and a burn-in device configured to carry the chips.

### BACKGROUND OF THE DISCLOSURE

A conventional burn-in testing apparatus includes a plurality of direct current (DC) power supplies, and each of the DC power supplies is connected to a plurality of chips under test at the same time. Therefore, an actual input voltage and an actual input current of the chips are difficult to be obtained, which can cause final test results of the chips under test to be lacking in reliability.

In addition, since a single one of the DC power supplies is connected to the chips, when two of the chips that are connected to a same one of the DC power supplies exhibit errors (e.g., incorrect signal measurements) during testing and a tester must follow relatively complex procedures to determine whether the errors originate in the chips or in the single DC power supply.

### SUMMARY OF THE DISCLOSURE

In response to the above-referenced technical inadequacies, the present disclosure provides a testing apparatus and a burn-in device for effectively improving the issues associated with the conventional burn-in testing apparatus, in which a single one of the DC power supplies is simultaneously connected to the multiple chips under test, which leads to the final test results of the chips lacking reliability.

In order to solve the above-mentioned problems, one of the technical aspects adopted by the present disclosure is to provide a testing apparatus. The testing apparatus is configured to enable a plurality of chips under test to be tested in a test process under a predetermined temperature. The testing apparatus includes an apparatus body, a processing device, a temperature adjustment device, an N number of direct current (DC) power supply modules, and at least one burn-in device. The apparatus body includes at least one chamber that includes at least one mating connector. The processing device is disposed in the apparatus body. The temperature adjustment device is disposed in the apparatus body. The processing device is electrically connected to the temperature adjustment device, and the processing device is configured to control the temperature adjustment device to increase or decrease a temperature of the at least one chamber to the predetermined temperature. The N number of the DC power supply modules is disposed in the apparatus body. At least one burn-in device is configured to be disposed in the at least one chamber, and the at least one burn-in device includes a circuit board and an M number of chip carriers. A side of the circuit board has at least one ground structure, a plurality of signal contact structures, and a P number of power supply contact structures, and the circuit board has a plurality of signal circuits and a plurality of power supply circuits. The signal contact structures are connected to the signal circuits, each of the power supply contact structures is connected to one of the power supply circuits, and the power supply circuits are not connected to each other. The circuit board is configured to be disposed in the at least one chamber, the at least one ground structure is connected to a ground circuit of the apparatus body, and each of the power supply contact structures is connected to each of the DC power supply modules through the at least one mating connector. The M number of the chip carriers are disposed on the circuit board, each of the chip carriers is configured to carry one of the chips under test. Each of the chip carriers is connected to one of the at least one ground structure and at least one of the signal circuits. N, M, and P are positive integers, N≥M, and P≥M. A power supply pin of the chip under test that is disposed on one of the chip carriers is electrically connected to one of the DC power supply modules through the corresponding chip carrier, the power supply circuits, one of the power supply contact structures, and the at least one mating connector. Each of the DC power supply modules is not connected to two of the chip carriers at a same time. The processing device is configured to perform the test process through a testing circuit to the chip under test that is arranged on each of the chip carriers. The processing device includes the testing circuit, or each of the DC power supply modules includes the testing circuit, and the processing device does not include the testing circuit.

In order to solve the above-mentioned problems, another one of the technical aspects adopted by the present disclosure is to provide a burn-in device. The burn-in device is disposed in a chamber of a testing apparatus. The testing apparatus includes an N number of direct current (DC) power supply modules. The chamber includes at least one mating connector. The burn-in device includes a circuit board and an M number of chip carriers. A side of the circuit board has at least one ground structure, a plurality of signal contact structures, and a P number of power supply contact structures, and the circuit board has a plurality of signal circuits and a plurality of power supply circuits. The signal contact structures are connected to the signal circuits, each of the power supply contact structures is connected to one of the power supply circuits, and the power supply circuits are not connected to each other. The circuit board is configured to be disposed in the at least one chamber, the at least one ground structure is connected to a ground circuit of the apparatus body, and each of the power supply contact structures is connected to each of the DC power supply modules through the at least one mating connector. The M number of the chip carriers are disposed on the circuit board, each of the chip carriers is configured to carry one of the chips under test. Each of the chip carriers is connected to one of the at least one ground structure and at least one of the signal circuits. N, M, and P are positive integers, N≥M, P≥M. A power supply pin of the chip under test that is disposed on one of the chip carriers is electrically connected to one of the DC power supply modules through the corresponding chip carrier, the power supply circuits, one of the power supply contact structures, and the at least one mating connector. Each of the DC power supply modules is not connected to two of the chip carriers at a same time. A processing device that is disposed in the testing apparatus is configured to perform the test process through a testing circuit to the chip under test that is arranged on each of the chip carriers. The processing device includes the testing circuit, or each of the DC power supply modules includes the testing circuit, and the processing device does not include the testing circuit.

Therefore, in the testing apparatus and the burn-in device provided by the present disclosure, by virtue of “the power supply pin of the chip under test on the chip carrier being electrically connected to the single one of the DC power supply modules,” the testing apparatus and the burn-in device can effectively control the voltage and the current input to the chip under test, such that the final test result of the chip under test has good reliability.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a testing apparatus according to the present disclosure;

FIG. 2 is a schematic block diagram of the testing apparatus according to the present disclosure;

FIG. 3 is a schematic top view of a circuit board of a burn-in device according to the present disclosure;

FIG. 4 is a schematic view of a monitoring interface of the testing apparatus according to the present disclosure; and

FIG. 5 is a schematic view showing a voltage waveform figure of the monitoring interface of the testing apparatus according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

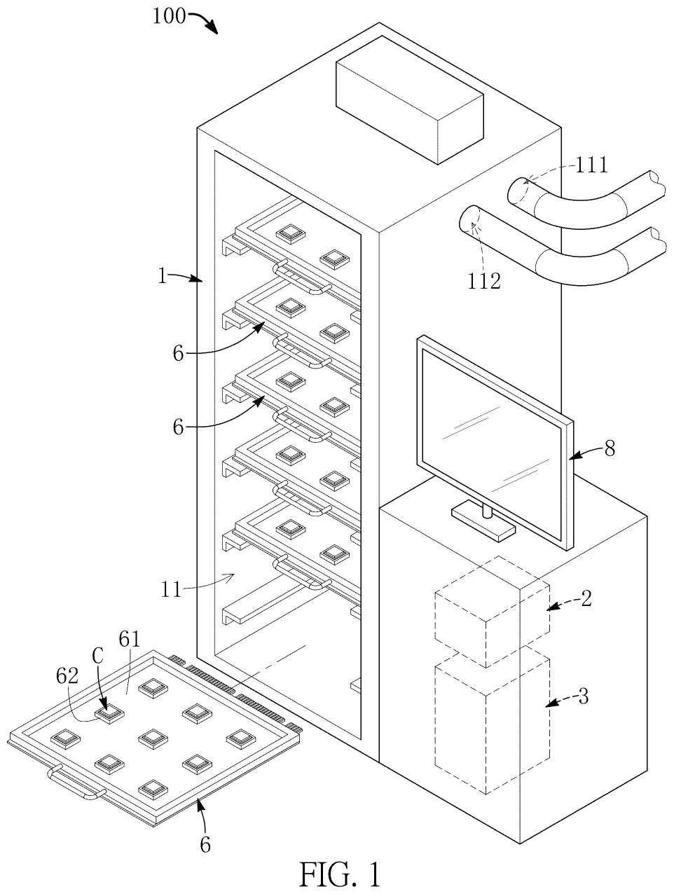

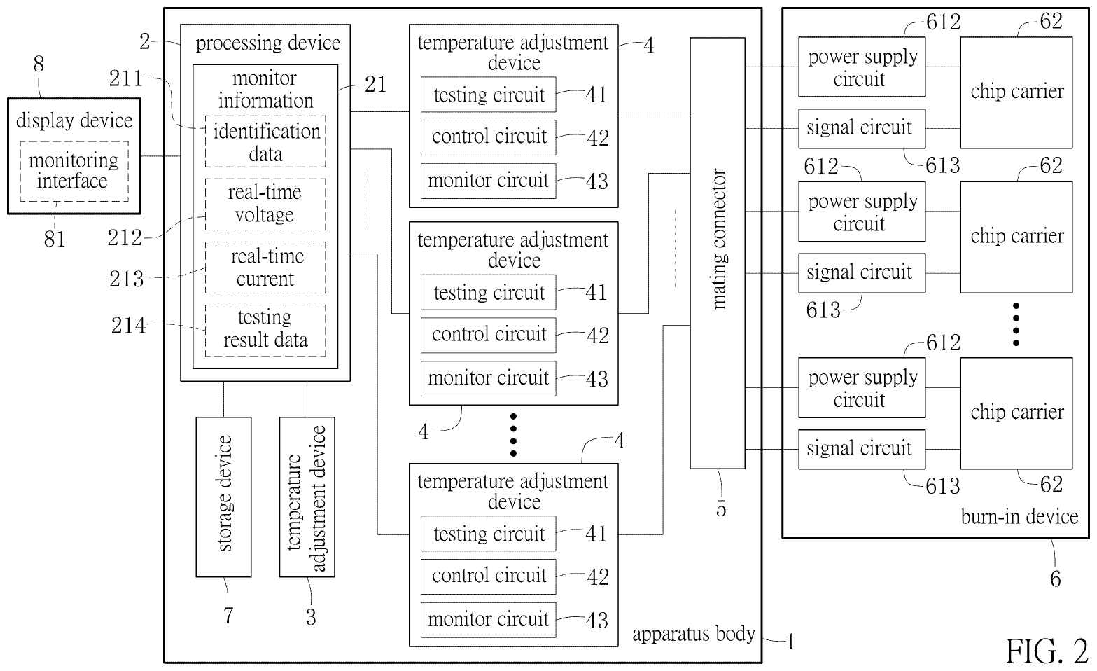

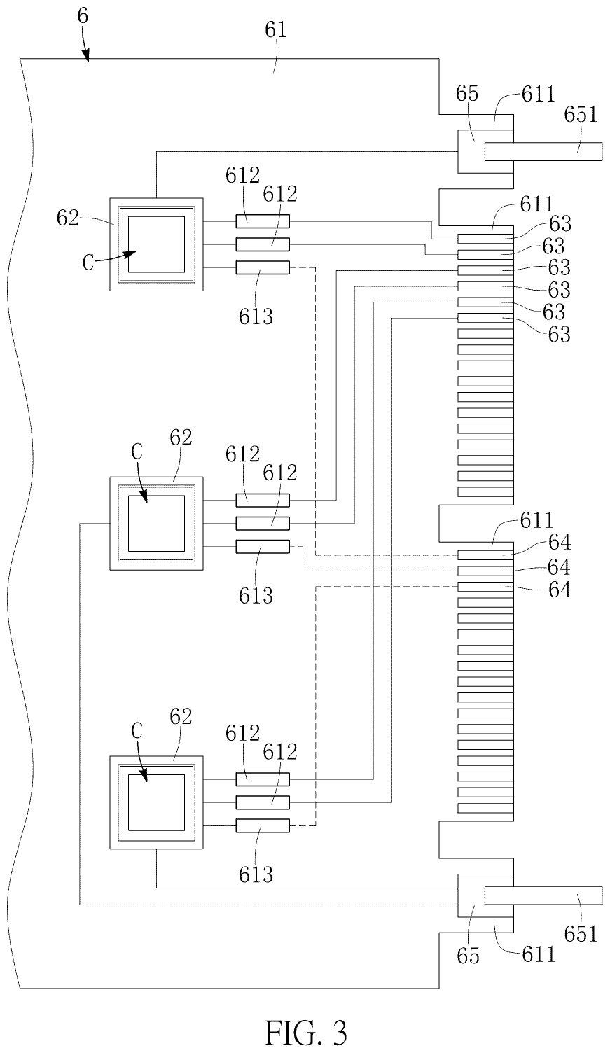

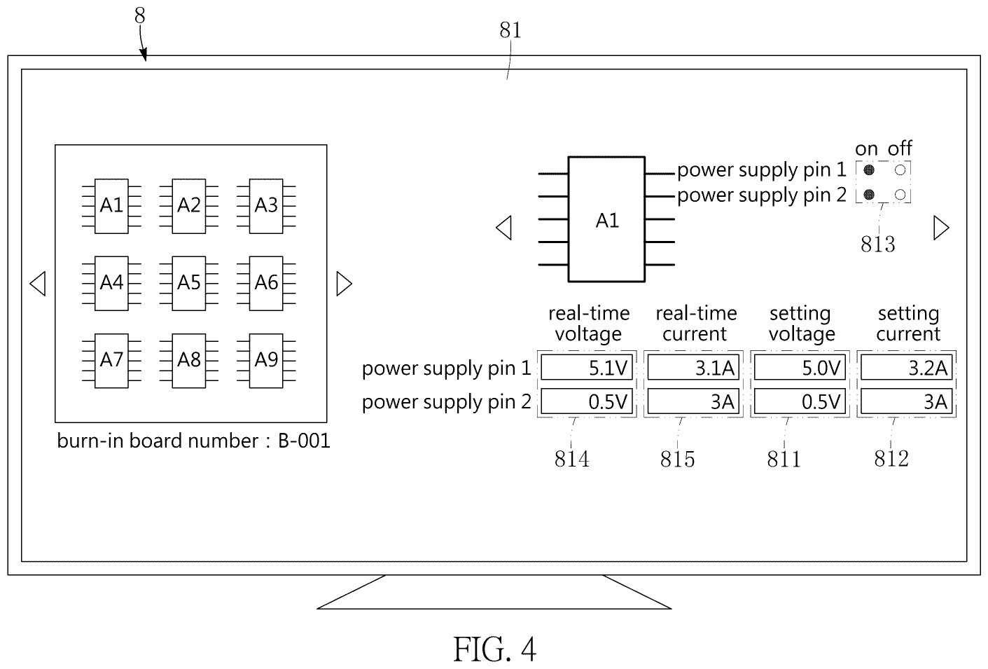

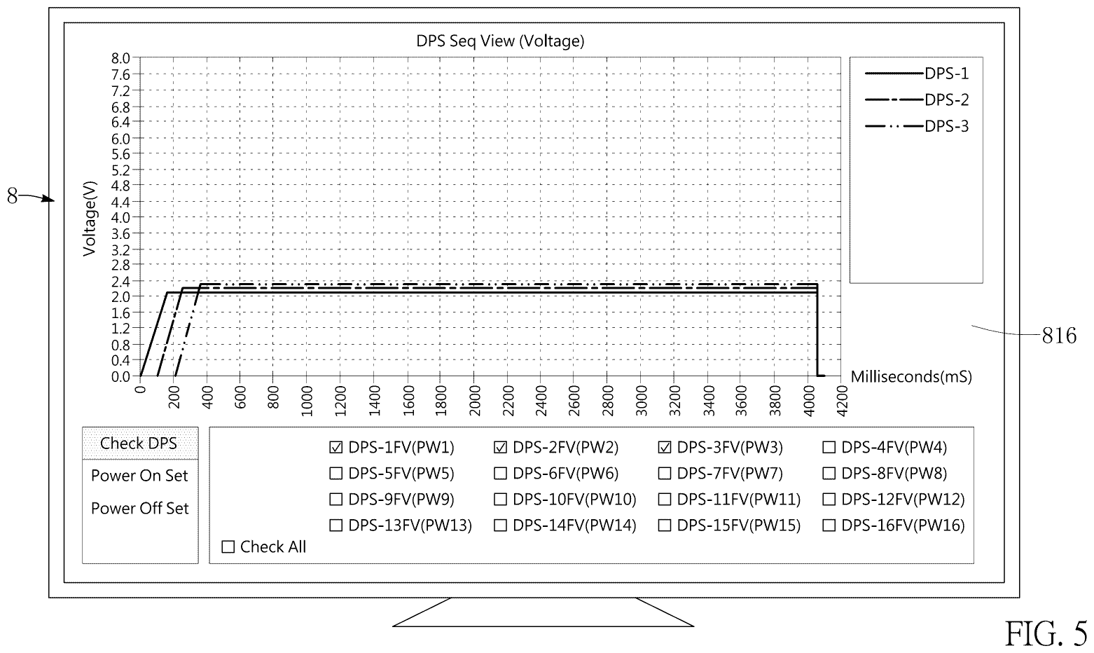

Referring to FIG. 1 to FIG. 5, FIG. 1 is a schematic view of a testing apparatus according to the present disclosure; FIG. 2 is a schematic block diagram of the testing apparatus according to the present disclosure; FIG. 3 is a schematic top view of a circuit board of a burn-in device according to the present disclosure; FIG. 4 is a schematic view of a monitoring interface of the testing apparatus according to the present disclosure; and FIG. 5 is a schematic view showing a voltage waveform figure of the monitoring interface of the testing apparatus according to the present disclosure.

A testing apparatus 100 of the present disclosure is configured to enable a plurality of chips C to be tested (hereinafter referred to as “the chips C”) in a test process at a predetermined temperature. The test process can be a burn-in test. Specific test items and processes of the burn-in test belong to conventional technologies, and will not be reiterated herein for the sake of brevity.

The testing apparatus 100 includes an apparatus body 1, a processing device 2, a temperature adjustment device 3, an N number of direct current (DC) power supply modules 4, at least one mating connector 5, and at least one burn-in device 6. The apparatus body 1 includes a chamber 11 that includes the mating connector 5 inside the chamber 11. The apparatus body 1 can include a casing and related electronic components required for an operation of the testing apparatus 100, such as a power supply device. A number of the chamber 11 included by the apparatus body 1 can be adjusted according to practical requirements, and is not limited to a single one. In different embodiments, the apparatus body 1 can include a plurality of chambers 11, which can be separate from each other by partitions or can be independent from each other.

The processing device 2 is disposed in the apparatus body 1, and the processing device 2 can be an industrial computer. The processing device 2 can be a main control system of the testing apparatus 100, but the present disclosure is not limited thereto. The temperature adjustment device 3 is disposed in the apparatus body 1, and the temperature adjustment device 3 can include a heater and a cooler. The processing device 2 is electrically connected to the temperature adjustment device 3, and the processing device 2 is configured to control the temperature adjustment device 3 to increase or decrease a temperature of the chamber 11 to the predetermined temperature. In the example where the apparatus body 1 includes multiple chambers 11, the apparatus body 1 can include multiple temperature adjustment devices 3, and the temperature in each of the chambers 11 is controlled by a corresponding one of the temperature adjustment devices 3.

In one of the embodiments, the chamber 11 has an air inlet 111 and an air outlet 112. The processing device 2 is configured to control a gas supply device to provide a predetermined gas (e.g., nitrogen or argon) to flow into the chamber 11 through the air inlet 111. The processing device 2 is configured to control an exhaust apparatus to extract the predetermined gas from the chamber 11 through the air outlet 112. The chamber 11 can be filled with the predetermined gas for preventing pins of the burn-in device 6 from having oxidation issues due to high temperatures and for allowing the temperature in all area of the chamber 11 to be more consistent, such that the chips C at different positions in the chamber 11 can have approximately the same temperature for the test process.

The N number of the DC power supply modules 4 are disposed in the apparatus body 1. Each of the DC power supply modules 4 is mainly configured to convert external utility power into direct current (DC) power of specific voltage and specific current. In one of the embodiments, each of the DC power supply modules 4 can provide exactly the same voltage and current. In different embodiments, a part of the N number of the DC power supply modules 4 can provide the same voltage and current, and another part of the N number of the DC power supply modules 4 can provide different voltages and currents.

The practical voltage and the practical current provided by each of the DC power supply modules 4 are not limited by the present embodiment. Preferably, each of the DC power supply modules 4 of the present disclosure provides small voltage and small current. For example, each of the DC power supply modules 4 of the present disclosure provides the voltage being within a range from 0.5 volts to 0.6 volts and the current being within a range from 3 amps to 6 amps, but the present disclosure is not limited thereto.

The burn-in device 6 is configured to be disposed in the chamber 11. The burn-in device 6 is configured to carry the chips C, and the burn-in device 6 is used as a bridge to connect the chips C and the processing device 2 disposed in the apparatus body 1. That is, through the burn-in device 6, the chips C disposed on the burn-in device 6 can obtain power that is provided by the DC power supply modules 4 and a testing signal that is transmitted by the processing device 2, and a signal that is returned by the chips C is also transmitted to the processing device 2 through the burn-in device 6.

The burn-in device 6 includes a circuit board 61 and an M number of chip carriers 62. A side of the circuit board 61 has a P number of power supply contact structures 63, a plurality of signal contact structures 64, and at least one ground structure 65. Each of the power supply contact structures 63 and each of the signal contact structures 64 can be made in the form of a gold finger, each of the power supply contact structures 63 is mainly used to transmit the power, and the signal contact structures 64 are mainly used to transmit signals. Each of the ground structures 65 is mainly used for grounding. In practice, the ground structure 65 can be made in the form of a gold finger, but the present disclosure is not limited thereto.

In one of the embodiments, the side of the circuit board 61 can have at least two protruding portions 611, the P number of the power supply contact structures 63 are disposed on the same one of the two protruding portions 611. Alternatively, the P number of the power supply contact structures 63 are disposed on a part of the protruding portions 611, the signal contact structures 64 are disposed on the remaining protruding portions 611, and each of the power supply contact structures 63 and each of the signal contact structures 64 are not disposed on the same one of the protruding portions 611. By the above-mentioned design, interference to the signal contact structures 64 can be significantly reduced.

The power supply contact structures 63 and the signal contact structures 64 that are disposed on the protruding portions 611 are mainly used to be plugged into the mating connector 5 located in the chamber 11. In the embodiment in which the ground structure 65 is in the form of the gold finger, the ground structure 65 can be disposed on one of the protruding portions 611, and the ground structure 65 is configured to be plugged into the mating connector 5 located in the chamber 11. After the power supply contact structures 63, the signal contact structures 64, and the ground structure 65 of the circuit board 61 are plugged into the mating connector 5 located in the chamber 11, the circuit board 61 can obtain the power transmitted by the DC power supply modules 4, and the processing device 2 can transmit the testing signal to the circuit board 61 and can receive the signal returned by the circuit board 61.

In one of the embodiments, a portion of the ground structure 65 can be connected to a conductive pillar 651, and a length of the conductive pillar 651 is greater than a length of each of the protruding portions 611. During a plugging process of a side of the circuit board 61 and the mating connector 5, the conductive pillar 651 can provide a guiding function and a positioning function, thereby ensuring that each of the power supply contact structures 63 and each of the signal contact structures 64 can be correctly plugged into the mating connector 5. A shape of each of the conductive pillars 651 can be designed according to practical requirements, and is not limited by the drawings. Correspondingly, the chamber 11 has a plurality of the engaging slots arranged around the mating connector 5 and corresponding in position to the conductive pillars 651, and each of the engaging slots is configured to allow a corresponding one of the conductive pillars 651 to insert therein. A quantity of the conductive pillars 651 and a position of the conductive pillars 651 on the circuit board 61 can be designed according to practical requirements, and are not limited by the drawings.

In different embodiments, the side of the circuit board 61 that has the power supply contact structures 63 and the signal contact structures 64 can have a plurality of leading positioning structures, each of the leading positioning structures can be a non-conductive structure (e.g., made of non-conductive plastic material), and a length of each of the leading positioning structures is greater than the length of each of the protruding portions 611. Corresponding positioning structures can be disposed around the mating connector 5 in the chamber 11, such that when the protruding portions 611 of the circuit board 61 and the mating connector 5 are plugged into each other, the leading positioning structures and the corresponding positioning structures are plugged into each other. During the plugging process of a side of the circuit board 61 and the mating connector 5, the leading positioning structures can provide a guiding function and a positioning function, thereby ensuring that each of the power supply contact structures 63 and each of the signal contact structures 64 can be correctly plugged into the mating connector 5. A quantity and a shape of the leading positioning structures and a position of the leading positioning structures disposed on the circuit board 61 can be changed according to practical requirements, and are not limited herein. In different embodiments, the leading positioning structures can be conductive structures, but the leading positioning structures are not connected to a ground circuit on the circuit board 61.

The circuit board 61 has a plurality of power supply circuits 612 and a plurality of signal circuits 613. Each of the power supply contact structures 63 is electrically connected to one of the power supply circuits 612, and the power supply circuits 612 are not connected to each other. The signal circuits 613 are connected to the signal contact structures 64. The power supply circuits 612 and the signal circuits 613 each include a layout circuit that is formed on the circuit board 61 and related electronic components. As shown in FIG. 3, simplified blocks are used to represent the power supply circuits 612 and the signal circuits 613, and the electronic components and functions of the power supply circuits 612 and the signal circuits 613 are not limited herein. For example, the power supply circuits 612 can include functions such as voltage stabilization and current stabilization, and the signal circuits 613 can include functions such as signal amplification and signal conversion. The functions belong to conventional technologies and will not be reiterated herein.

The M number of the chip carriers 62 (e.g., sockets) are disposed on the circuit board 61. Each of the chip carriers 62 is configured to carry one of the chips C. Each of the chip carriers 62 is connected to the ground structure 65, each of the chip carriers 62 is connected to at least one of the power supply circuits 612, and each of the chip carriers 62 is connected to at least one of the signal circuits 613. When the power supply contact structures 63 and the signal contact structures 64 of the circuit board 61 are plugged into the mating connector 5 located in the chamber 11, each of the DC power supply modules 4 is connected to one of the chip carriers 62 through the mating connector 5, one of the power supply contact structures 63, and the power supply circuit 612 that is connected to the one of the power supply contact structures 63, thereby enabling each of the DC power supply modules 4 to be electrically connected to one of the power supply pins of the chip C disposed on the chip carriers 62.

Accordingly, each of the power supply circuits 612 mainly serves as an electrical connection bridge between one of the power supply pins of the chip C that is disposed on the chip carrier 62 and one of the power supply contact structures 63. Each of the signal circuits 613 mainly serves as a connection bridge between one of signal pins of the chip C that is disposed on the chip carrier 62 and one of the signal contact structures 64 of the circuit board 61.

It is worth mentioning that, the testing apparatus 100 of the present disclosure includes the N number of the DC power supply modules 4, the M number of the chip carriers 62, and the P number of the power supply contact structures 63, in which N, M, and P are positive integers, N≥M, and P≥M. That is, a quantity of the DC power supply modules 4 that are included by the testing apparatus 100 is greater than or equal to a quantity of the chip carriers 62; a quantity of the P number of the power supply contact structures 63 that are included by the testing apparatus 100 is greater than or equal to a quantity of the chip carriers 62. The chip C of each of the chip carriers 62 is electrically connected to at least one of the DC power supply modules 4 through the chip carrier 62 and at least one of the power supply contact structures 63, and a single one of the DC power supply modules 4 is electrically connected to one of the power supply pins of the chip C on a single one of the chip carriers 62 through only a single one of the power supply contact structures 63.

In summary, the voltage and the current entering one of the power pins of the chip C can be accurately controlled by the DC power supply module 4, thereby ensuring that the a specific voltage and a specific current are input into the chip C before the test process are performed.

It should be noted that, each of the DC power supply modules 4 of the present disclosure is not connected to two of the chip carriers 62 at the same time. That is, the single one of the DC power supply modules 4 does not provide the power to the two of the chips C that are disposed on two of the chip carriers 62 at the same time, the single one of the DC power supply modules 4 of the present disclosure is only electrically connected to one of the power supply pins of the chip C that is disposed on one of the chip carriers 62, and the single one of the DC power supply modules 4 is not electrically connected to both of one of the power supply pins of two of the chips C at the same time.

In practice, the voltage and the current provided by each of the DC power supply modules 4 can be determined by the voltage and the current that are required for operation of the chip C, and the voltage and the current that are required by the chip C are greater than or equal to the voltage and the current that are provided by each of the DC power supply modules 4. That is to say, during the test process of the single one of the chips C, the single one of the chips C needs to be powered by one or more of the DC power supply modules 4. In other words, each of the power supply pins of the chip C that is disposed on one of the chip carriers 62 is connected to the single one of the DC power supply modules 4.

In the embodiment where each of the chips C has a plurality of the power supply pins, each of the chip carriers 62 is connected to the DC power supply modules 4, the different power supply pins of the chip C that is disposed on each of the chip carriers 62 are electrically connected to different ones of the DC power supply modules 4, and the different DC power supply modules 4 provide the power to different ones of the power supply pins of the same chip C. Therefore, different voltages and currents are input by the different DC power supply modules 4 to the different power supply pins of the chip C that is disposed on one of the chip carriers 62.

In the conventional technology, the single one of the DC power supplies of the testing apparatus simultaneously provides the power to multiple ones of the chips under test on the chip carriers. Therefore, the relevant (operating) personnel cannot effectively confirm the practical voltage and the practical current input to the chip C. In addition, since the single one of the DC power supplies provides the power to the chips under test on the chip carriers at the same time, even if the relevant personnel find that the voltage or the current that enters one of the chips under test is greater than or is less than the required voltage or the required current, it is also difficult for relevant personnel to change the voltage or the current. Furthermore, if an output voltage and/or an output current of the corresponding DC power supply is adjusted for a single one of chips under test, the input voltage and the input current for other chips under test carried by the chip carriers connected to the same DC power supply are directly or indirectly changed.

When the power supply contact structures 63 and the signal contact structures 64 of the circuit board 61 are plugged into the mating connector 5 that is located in the chamber 11, the processing device 2 is configured to perform the test process (e.g., a current test, a voltage test, etc., and are not limited herein) on the chip C of each of the chip carriers 62 through a testing circuit 41. The processing device 2 includes the testing circuit 41, or each of the DC power supply modules 4 includes the testing circuit 41, and the circuit board 61 does not include the testing circuit 41. Since the circuit board 61 of the burn-in device 6 is configured to be disposed in the chamber 11, and the circuit board 61 can have a predetermined temperature in the chamber 11, arranging the testing circuit 41 in the processing device 2 or the DC power supply module 4 can significantly reduce the risk of the testing circuit 41 being damaged due to being located in the chamber 11 having a high or low temperature.

In other words, in conventional testing apparatuses, a testing circuit is disposed on a burn-in board (BIB). Therefore, in manufacturing, when selecting the electronic components included in the testing circuit, electronic components having high-temperature and low-temperature resistance need to be selected, so as to prevent the electronic components included in the testing circuit from being damaged when the burn-in board is tested in a high or low temperature environment.

Since the testing circuit 41 of the present disclosure is not disposed on the circuit board 61 of the burn-in device 6, the capability of the electronic components used in the testing circuit 41 to withstand the high and low temperatures in the chamber 11 does not need to be considered. Therefore, a production cost of the testing circuit 41 can be effectively reduced, and a probability of damage being dealt to the testing circuit 41 can be greatly reduced. The testing circuit 41 can perform the following tests on the chip C, and the tests include high temperature operating life/low temperature operating life (HTOL/LTOL), bias life test, early life failure rate (ELFR), non-volatile memory endurance, data retention, and operational life (NVM EDR), discrete semiconductor life tests (e.g., HTGB, HTRB, IOL, PTC, H3TRB, etc.) and are not limited herein.

Furthermore, by arranging the testing circuit 41 in the processing device 2 or the DC power supply module 4 instead of on the circuit board 61 of the burn-in device 6, a manufacturing cost and a manufacturing difficulty of the circuit board 61 of the burn-in device 6 can be greatly reduced. In practice, with the increase of functions of the chips C, more and more pins are configured in the chips C. Therefore, the overall design of the circuit board 61 becomes increasingly complex, and if the testing circuit is still disposed on the burn-in board according to the conventional design, the manufacturing cost and the manufacturing difficulty of the burn-in board will become increasingly higher.

It is worth mentioning that, since the single one of the DC power supply modules 4 is connected to one of the power supply pins of the chip C, in one of the embodiments, each of the DC power supply modules 4 can have the testing circuit 41, and the processing device 2 can perform the test process on the corresponding DC power supply module 4 and the chip C that is connected to the corresponding DC power supply module 4 through each of the testing circuits 41.

Naturally, a quantity and a position of the testing circuit 41 are not limited to the above descriptions. In different embodiments, the testing circuits 41 can be integrated into the processing device 2, and a processor in the processing device 2 can perform the test process on the chips C through the testing circuits 41 and the DC power supply modules 4.

In the example where the chip C includes the power supply pins, the power supply pins of the chip C can be connected to the DC power supply modules 4 through the chip carrier 62 and the power supply circuits 612. For example, assuming that the chip C has three power supply pins, the three power supply pins of the chip C can correspondingly be electrically connected to three of the DC power supply modules 4 through the chip carrier 62, three of the power supply circuits 612, and three of the power supply contact structures 63, and the three of the DC power supply modules 4 can respectively provide the necessary voltage and the necessary current to the three power supply pins of the chip C.

In practice, each of the DC power supply modules 4 can be connected to a control circuit 42, the control circuit 42 is electrically connected to the processing device 2, and the processing device 2 is configured to selectively turn off through the control circuit 42 a power supply relationship between one of the DC power supply modules 4 and one of the chip carriers 62 that is connected to the one of the DC power supply modules 4. That is to say, the processing device 2 can control whether or not any one of the DC power supply modules 4 provides the power to one of the power supply pins of the chip C on the chip carrier 62 according to practical requirements. In practice, the control circuit 42 can include a switching circuit (not shown in the drawings), but the present disclosure is not limited thereto. In different embodiments, in addition to the switching circuit, the control circuit 42 can also include a transformer circuit, etc., and the processing device 2 is configured to control the DC power supply module 4 through the control circuit 42 to change the voltage input to one of the power supply pins of the chip C.

As shown in FIG. 4, in practice, the testing apparatus 100 can be connected to a display device 8. The display device 8 can be a device independent of the testing apparatus 100, or the testing apparatus 100 can include the display device 8. The processing device 2 is electrically connected to the display device 8, and the processing device 2 is configured to control the display device 8 to display a monitoring interface 81. The monitoring interface 81 includes a voltage setting field 811, a current setting field 812, a switching field 813, a real-time voltage field 814, and a real-time current field 815, the voltage setting field 811 is used to allow a user to input a setting voltage, and the current setting field 812 is used to allow the user to input a setting current, and the setting voltage and the setting current correspond to an input voltage and an input current of one of the power supply pins of one of the chips C. The switching field 813 is used to provide the user to select turning on or turning off the power supply relationship between one of the power supply pins of the chip C and the corresponding DC power supply module 4.

The processing device 2 is configured to control the corresponding DC power supply module 4 through the control circuit 42 according to the above-mentioned setting voltage and the above-mentioned setting current, such that the corresponding DC power supply module 4 transmits a corresponding setting voltage and a corresponding setting current to the corresponding power supply pin of the chip C on the corresponding chip carrier 62.

As shown in FIG. 5, in a preferred embodiment, the processing device 2 is configured to control the monitoring interface 81 to display a voltage waveform FIG. 816 corresponding to a voltage of each of the chips C. In the monitoring interface 81, the monitoring interface 81 can include a plurality of options (i.e., DPS-1 FV (FW1), DPS-2 FV (FW2), etc., as shown in the figure), and the user can select from different options to display a voltage waveform corresponding to the corresponding power supply pin in the voltage waveform FIG. 816.

As shown in FIG. 4, in the monitoring interface 81, the user sets the two switching fields 813 corresponding to the power supply pin 1 and the power supply pin 2 of the chip labeled A1 in the figure to be on, and the user sets 5.0 V and 0.5 V respectively in two of the voltage setting fields 811 corresponding to the power supply pin 1 and the power supply pin 2, and the user sets 3.2 A and 3 A respectively in two of the current setting fields 812 corresponding to the power supply pin 1 and the power supply pin 2. After the above settings are completed, the processing device 2 is configured to control the two corresponding DC power supply modules 4, such that one of the DC power supply modules 4 provides a 5 V and 3.2 A power to the power supply pin 1 of the chip labeled Al in the figure, and another one of the DC power supply modules 4 provides a 0.5 V and 3 A power to the power supply pin 2 of the chip labeled A1 in the figure.

As shown in FIG. 2 and FIG. 4, in practice, the processing device 2 is configured to obtain a real-time current 213 and a real-time voltage 212 that are input from each of the DC power supply modules 4 to one of the power supply pins of one of the chips C that is disposed on one of the chip carriers 62 through a plurality of monitor circuits 43. The monitor circuits 43 are disposed on the circuit board 61, the processing device 2, or the DC power supply modules 4.

In the example where the processing device 2 is configured to obtain the real-time current 213 and the real-time voltage 212 of each of the power supply pins of each of the chips C through the monitor circuits 43, the processing device 2 can display the real-time voltage 212 and real-time current 213 corresponding to each of the power supply pins of each of the chips C in the monitoring interface 81, and the user can instantly know the setting voltage and the setting current of each of the power supply pins of each of the chips C and the practical input real-time voltage and the practical input real-current through the real-time voltage field 814 and the real-time current field 815 of the monitoring interface 81.

In the conventional technology, since a single DC power supply provides the power to multiple chips under test at the same time, the relevant personnel are unable to know the practical real-time voltage and the practical real-time current input to the chip under test. In addition, in conventional technologies, the chips under test that are connected to the same DC power supply have voltage drop issues. That is, the actual input voltage of the chip under test that is farther away from the DC power supply can be lower than the predetermined voltage.

Furthermore, it is worth mentioning that, in the conventional technology, the chips under test on the burn-in board are usually connected to a same power supply. Therefore, when one of the chips under test burns out, a large current can flow through the circuit that is connected to the chip under test. Accordingly, it is possible that other functioning chips located on the same circuit board be burned out together. Eventually, all the chips on the burn-in board may be destroyed.

In the testing apparatus 100 of the present disclosure, each of the power supply pins of each of the chips C is connected to the single one of the DC power supply modules 4, such that the voltage drop issue in the above-mentioned conventional technology does not occur. Through the design of the monitor circuit 43 and the control circuit 42, the relevant personnel can monitor the input voltage and the input current in real time, and the relevant personnel can accurately know the specific input voltage and the specific input current of each of the chips C during the test process. In addition, the power supply pins of each of the chips C are connected to the single one of the DC power supply modules 4. Therefore, when one of the chips C is burned out, the large current instantly flows through the circuit connected to the chip C does not affect other portions of the chips C, and can prevent the other portions of the chips C from burning out at the same time.

It is worth mentioning that, in the example where the processing device 2 is configured to obtain the real-time current and the real-time voltage of each of the power supply pins of each of the chips C through the monitor circuits 43, the processing device 2 is configured to store a plurality of monitor information in a storage device 7 that is disposed in the apparatus body 1, and each piece of monitor information 21 corresponds to an identification data 211 for one of the chips C, as well as the real-time voltage and the real-time current associated with the chip C during the test process. The monitor information 21 can further include a testing result data 214. With this design, a tester will be able to trace back the previous test records of each of the chips C by obtaining the monitor information 21 in the storage device 7.

Through the above design, each of the chips C using the testing apparatus 100 of the present disclosure can be able to comply with the relevant specifications of some countries for electronic components used in automobiles because the relevant records of the tests are retained. For example, some countries stipulate that production records related to chips used in automobiles need to be kept for at least 5 years for future traceability. It should be noted that, the real-time voltage 212 and the real-time current 213 included in each piece of the monitor information 21 can respectively be an average real-time voltage and an average real-time current of all measurements of the chip C during the test process.

It should be noted that, the burn-in device 6 of the present disclosure can be sold and manufactured independently of the testing apparatus 100, and the burn-in device 6 is not limited to being sold and manufactured together with the testing apparatus 100.

### Beneficial Effects of the Embodiments

In conclusion, in the testing apparatus and the burn-in device provided by the present disclosure, by virtue of “the power supply pin of the chip under test on the chip carrier being electrically connected to the single one of the DC power supply modules,” the testing apparatus and the burn-in device can effectively control the voltage and the current input to the chip under test, such that the final test result of the chip under test has good reliability.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A testing apparatus configured to enable a plurality of chips under test to be tested in a test process under a predetermined temperature, the testing apparatus comprising:
an apparatus body including at least one chamber that includes at least one mating connector;
a processing device disposed in the apparatus body;
a temperature adjustment device disposed in the apparatus body;
wherein the processing device is electrically connected to the temperature adjustment device, and the processing device is configured to control the temperature adjustment device to increase or decrease a temperature of the at least one chamber to the predetermined temperature;
an N number of direct current (DC) power supply modules disposed in the apparatus body; and
at least one burn-in device configured to be disposed in the at least one chamber, the at least one burn-in device including:
a circuit board, wherein a side of the circuit board has at least one ground structure, a plurality of signal contact structures, and a P number of power supply contact structures, and the circuit board has a plurality of signal circuits and a plurality of power supply circuits;
wherein the signal contact structures are connected to the signal circuits, each of the power supply contact structures is connected to one of the power supply circuits, and the power supply circuits are not connected to each other; and wherein the circuit board is configured to be disposed in the at least one chamber, the at least one ground structure is connected to a ground circuit of the apparatus body, and each of the power supply contact structures is connected to each of the DC power supply modules through the at least one mating connector; and
an M number of chip carriers disposed on the circuit board, wherein each of the chip carriers is configured to carry one of the chips under test; wherein each of the chip carriers is connected to one of the at least one ground structure and at least one of the signal circuits; and wherein N, M, and P are positive integers, N≥M, and P≥M;
wherein a power supply pin of the chip under test that is disposed on one of the chip carriers is electrically connected to one of the DC power supply modules through the corresponding chip carrier, the power supply circuits, one of the power supply contact structures, and the at least one mating connector; and wherein each of the DC power supply modules is not connected to two of the chip carriers at a same time;
wherein the processing device is configured to perform the test process through a testing circuit to the chip under test that is arranged on each of the chip carriers; and
wherein the processing device includes the testing circuit, or each of the DC power supply modules includes the testing circuit, and the processing device does not include the testing circuit.

2. The testing apparatus according to claim 1, wherein a voltage and current provided by each of the DC power supply modules are less than or equal to a voltage and current required for an operation of the chip under test.

3. The testing apparatus according to claim 1, wherein the side of the circuit board has a plurality of protruding portions, and each of the power supply contact structures and each of the signal contact structures are not disposed on a same one of the protruding portions; wherein the side of the circuit board that has the protruding portions includes a plurality of conductive pillars, the at least one ground structure is plural in quantity, and the conductive pillars are electrically connected to the ground structures; and wherein the protruding portions are configured to plug into the at least one mating connector in the at least one chamber, a length of each of the conductive pillars is greater than a length of each of the protruding portions, and the conductive pillars are configured to guide the protruding portions and the mating connector to be plugged into each other.

4. The testing apparatus according to claim 3, wherein the side of the circuit board that has the protruding portions further includes a plurality of leading positioning structures, a length of each of the leading positioning structures is greater than the length of each of the conductive pillars; and wherein the leading positioning structures are configured to guide the protruding portions and the mating connector to be plugged into each other and are configured to plug into a positioning structure arranged adjacent to the mating connector.

5. The testing apparatus according to claim 1, wherein each of the DC power supply modules is connected to a control circuit that is electrically connected to the processing device, and the processing device is configured to selectively turn off a power supply relationship between one of the DC power supply modules and one of the chip carriers that is connected to the one of the DC power supply modules through the control circuit.

6. The testing apparatus according to claim 5, wherein the testing apparatus is connected to a display device, and the processing device is configured to control a monitoring interface of the display device to display a plurality of voltage setting fields, a plurality of current setting fields, and a plurality of switching fields that correspond to the chip carriers; wherein each of the voltage setting fields is used to allow a user to input a setting voltage, and each of the current setting fields is used to allow the user to input a setting current; wherein the processing device is configured to turn off the power supply relationship between the corresponding DC power supply module and the corresponding chip carrier through the control circuit according to an open status and a closed status of each of the switching fields; and wherein the processing device is configured to control the corresponding DC power supply module through the control circuit according to each of the setting voltages and the setting currents, such that the corresponding DC power supply module transmits a corresponding one of the setting voltages and a corresponding one of the setting currents to the chip under test on the corresponding chip carrier.

7. The testing apparatus according to claim 1, wherein each of the chips under test has a plurality of the power supply pins; and wherein any different two of the power supply pins of the chip under test disposed on each of the chip carriers are electrically connected to different two of the DC power supply modules and are supplied with a same or different voltages and currents by the different two of the DC power supply modules.

8. The testing apparatus according to claim 1, wherein the at least one chamber has an air inlet and an air outlet; wherein the processing device is configured to control a gas supply device to provide a predetermined gas to flow into the at least one chamber through the air inlet; and wherein the processing device is configured to control an exhaust apparatus to extract the predetermined gas from the at least one chamber through the air outlet.

9. The testing apparatus according to claim 1, wherein the processing device is configured to obtain a real-time current and a real-time voltage that are inputted from each of the DC power supply modules to one of the power supply pins of one of the chips under test that is disposed on one of the chip carriers through a plurality of monitor circuits; and wherein the monitor circuits are disposed on the circuit board, the processing device, or the DC power supply modules.

10. The testing apparatus according to claim 9, wherein the processing device is configured to store monitor information of each of the chips under test in a storage device of the testing apparatus; and wherein the monitor information includes identification data of each of the chips under test and the real-time current and the real-time voltage corresponding to each of the chips under test during the test process.

11. The testing apparatus according to claim 10, wherein the testing apparatus is connected to a display device, the processing device is electrically connected to the display device, and the processing device is configured to transmit at least one of the real-time current and the real-time voltage corresponding to each of the chips under test to the display device, such that a monitoring interface displayed by the display device is configured to display the real-time current and the real-time voltage corresponding to each of the power supply pins of each of the chips under test.

12. The testing apparatus according to claim 11, wherein the processing device is configured to control the monitoring interface to display a waveform diagram corresponding to a voltage or a power output change over time of each of the DC power supply modules.

13. A burn-in device disposed in a chamber of a testing apparatus, the testing apparatus including an N number of direct current (DC) power supply modules, the chamber including at least one mating connector, and the burn-in device comprising:
a circuit board, wherein a side of the circuit board has at least one ground structure, a plurality of signal contact structures, and a P number of power supply contact structures, and the circuit board has a plurality of signal circuits and a plurality of power supply circuits; wherein the signal contact structures are connected to the signal circuits, each of the power supply contact structures is connected to one of the power supply circuits, and the power supply circuits are not connected to each other, and wherein the circuit board is configured to be disposed in the at least one chamber, the at least one ground structure is connected to a ground circuit of the apparatus body, and each of the power supply contact structures is connected to each of the DC power supply modules through the at least one mating connector; and
an M number of chip carriers disposed on the circuit board, wherein each of the chip carriers configured to carry one of the chips under test; wherein each of the chip carriers is connected to one of the at least one ground structure and at least one of the signal circuits; and wherein N, M, and P are positive integers, N≥M, P≥M;
wherein a power supply pin of the chip under test that is disposed on one of the chip carriers is electrically connected to one of the DC power supply modules through the corresponding chip carrier, the power supply circuits, one of the power supply contact structures, and the at least one mating connector; and wherein each of the DC power supply modules is not connected to two of the chip carriers at a same time;
wherein a processing device that is disposed in the testing apparatus is configured to perform the test process through a testing circuit to the chip under test that is arranged on each of the chip carriers; and
wherein the processing device includes the testing circuit, or each of the DC power supply modules includes the testing circuit, and the processing device does not include the testing circuit.

14. The burn-in device according to claim 13, wherein each of the chips under test has a plurality of the power supply pins; wherein any different two of the power supply pins of the chips under test disposed on each of the chip carriers are electrically connected to different two of the DC power supply modules; and are supplied with a same or different voltages and currents by the different two of the DC power supply modules.

15. The burn-in device according to claim 13, wherein the side of the circuit board has a plurality of protruding portions, and each of the power supply contact structures and each of the signal contact structures are not disposed on a same of the protruding portions; wherein the side of the circuit board that has the protruding portions includes a plurality of conductive pillars, the at least one ground structure is plural in quantity, and the conductive pillars are electrically connected to the ground structure; and wherein the protruding portions are configured to plug into the at least one mating connector in the at least one chamber, a length of each of the conductive pillars is greater than a length of each of the protruding portions, and the conductive pillars are configured to guide the protruding portions and the mating connector to be plugged into each other.

16. The burn-in device according to claim 15, wherein the side of the circuit board that has the protruding portions further includes a plurality of leading positioning structures, a length of each of the leading positioning structures is greater than the length of each of the conductive pillars; and wherein the leading positioning structures are configured to guide the protruding portions and the mating connector to be plugged into each other and are configured to plug into a positioning structure arranged adjacent to the mating connector.
